(19) United States
(12) Patent Application Publication
(10) Pub. No.: US 2025/0126894 A1
(43) Pub. Date: Apr. 17, 2025

(54) THIN FILM TRANSISTOR SUBSTRATE AND ELECTRONIC DEVICE COMPRISING THE SAME

(71) Applicants: InnoLux Corporation, Miao-Li County (TW); CARUX TECHNOLOGY PTE. LTD., SINGAPORE (SG)

(72) Inventors: Li-Wei SUNG, Tainan (Tainan Science Park) (TW); Cheng-Tso CHEN, Miao-Li County (TW); Hung-Kun CHEN, Miao-Li County (TW); Cheng-Tai KANG, Miao-Li County (TW)

(21) Appl. No.: 18/828,258

(22) Filed: Sep. 9, 2024

(30) Foreign Application Priority Data
Oct. 11, 2023 (CN) 202311312052.8

(51) Int. Cl. H01L 27/12

(52) U.S. Cl. CPC H10D 86/60; H10D 86/451; H10D 86/441

(57) ABSTRACT

A thin film transistor substrate includes a substrate, a first metal layer disposed on the substrate, a second metal layer disposed on the first metal layer, a semiconductor disposed between the substrate and the first metal layer, and a first insulating layer disposed between the first metal layer and the second metal layer. The first metal layer includes a gate pattern, the second metal layer includes a scan line pattern, the semiconductor includes an active region, and the first insulating layer includes a first opening. The gate pattern overlaps the active region, and the scan line pattern of the second metal layer is electrically connected to the gate pattern of the first metal layer through the first opening in the first insulating layer.

### CROSS REFERENCE TO RELATED APPLICATIONS

This application claims priority of China Patent Application No. 202311312052.8, filed on Oct. 11, 2023, the entirety of which is incorporated by reference herein.

### BACKGROUND OF THE INVENTION

### Field of the Invention

The present disclosure relates to semiconductor technology, and in particular it relates to a thin film transistor substrate.

### Description of the Related Art

Liquid-crystal displays (LCD) have gradually replaced traditional cathode ray tube (CRT) displays thanks to their advantages, which include low radiation, small size, and low power consumption. As a result, they are widely used in notebook computers, personal digital assistants (PDAs), flat panel TVs, mobile phones, and other information technology products. However, a large-size LCD has the disadvantage of insufficient pixel charging due to excessive scan line loading.

### BRIEF SUMMARY OF THE INVENTION

The present disclosure provides a thin film transistor substrate and an electronic device including the same.

An embodiment of the present disclosure provides a thin film transistor substrate. The thin film transistor substrate includes a substrate, a first metal layer disposed on the substrate, a second metal layer disposed on the first metal layer, a semiconductor disposed between the substrate and the first metal layer, and a first insulating layer disposed between the first metal layer and the second metal layer. The first metal layer includes a gate pattern, the second metal layer includes a scan line pattern, the semiconductor includes an active region, and the first insulating layer includes a first opening. The gate pattern overlaps the active region, and the scan line pattern of the second metal layer is electrically connected to the gate pattern of the first metal layer through the first opening in the first insulating layer.

An embodiment of the present disclosure provides an electronic device including a thin film transistor substrate. The thin film transistor substrate includes a substrate, a first metal layer disposed on the substrate, a second metal layer disposed on the first metal layer, a semiconductor disposed between the substrate and the first metal layer, and a first insulating layer disposed between the first metal layer and the second metal layer. The first metal layer includes a gate pattern, the second metal layer includes a scan line pattern, the semiconductor includes an active region, and the first insulating layer includes a first opening. The gate pattern overlaps the active region, and the scan line pattern of the second metal layer is electrically connected to the gate pattern of the first metal layer through the first opening in the first insulating layer.

### BRIEF DESCRIPTION OF THE DRAWINGS

The present invention can be more fully understood by reading the subsequent detailed description and examples with references made to the accompanying drawings, wherein:

FIG. 1 is a partial top schematic view of a thin film transistor substrate according to an embodiment of the present disclosure;

FIG. 2 is a partial cross-sectional schematic view of a thin film transistor substrate taken along a line I-I′ shown in FIG. 1;

FIG. 3A is a partial top schematic view of a structure in which a light shielding layer is formed on a substrate according to an embodiment of the present disclosure;

FIG. 3B is a partial top schematic view of a structure in which a semiconductor is further formed on the structure of FIG. 3A according to an embodiment of the present disclosure;

FIG. 3C is a partial top schematic view of a structure in which a first metal layer is further formed on the structure of FIG. 3B according to an embodiment of the present disclosure;

FIG. 3D is a partial top schematic view of a structure in which a first insulating layer is further formed on the structure of FIG. 3C according to an embodiment of the present disclosure;

FIG. 3E is a partial top schematic view of a structure in which a second metal layer is further formed on the structure of FIG. 3D according to an embodiment of the present disclosure;

FIG. 4 is a partial cross-sectional schematic view of the structure shown in FIG. 3E taken along a line II-II′;

FIG. 5A is a partial top schematic view of a thin film transistor substrate according to an embodiment of the present disclosure;

FIG. 5B is a partial cross-sectional schematic view of the structure shown in FIG. 5A taken along a line III-III′;

FIG. 6A is a partial top schematic view of a thin film transistor substrate according to an embodiment of the present disclosure;

FIG. 6B is a partial cross-sectional schematic view of the structure shown in FIG. 6A taken along a line IV-IV′;

FIG. 7 is a partial top schematic view of a thin film transistor substrate according to an embodiment of the present disclosure; and

FIG. 8 is a partial top schematic view of a thin film transistor substrate according to an embodiment of the present disclosure.

### DETAILED DESCRIPTION OF THE INVENTION

The following is a detailed description of the electronic device according to the embodiment of the present disclosure. The following disclosure provides many different embodiments, or examples, for implementing different features of the provided subject matter. Specific examples of components and arrangements are described below to simplify the present disclosure. These are, of course, merely examples and are not intended to be limiting. In addition, repeated symbols or labels may be used in different embodiments. These repetitions are made only for the purpose of briefly and clearly describing some embodiments of the present disclosure and do not imply any correlation between the different embodiments and/or structures discussed.

In the disclosure, the terms “about”, “approximately”, and “roughly” usually indicate a value of a given value or range that varies within 10%, or within 5%, or within 3%, or within 2%, or within 1%, or within 0.5%. A given value here is an approximate value, i.e., the meanings of “about”, “approximately”, and “roughly” may be implied in the absence of the terms “about”, “roughly”, and “roughly”. In the disclosure, the term “a-b” indicates a value which is greater than or equal to a and less than or equal to b.

It should be understood that, although the terms “first”, “second”, “third” etc. are used herein to describe various elements, components, areas, layers, and/or parts, these elements, components, areas, layers, and/or parts should not be limited by these terms. These terms are only used to distinguish one elements, components, areas, layers, and/or parts from other elements, components, areas, layers, and/or parts. Thus, a first element, component, area, layer, or part discussed below could be termed as a second element, component, area, layer, or part without departing from the teachings of the present disclosure.

It should be understood that relative terms such as “under”, “on”, “horizontal”, “vertical”, “below”, “above”, “top”, “bottom”, etc. shall be construed to indicate orientations shown in the paragraph and the related accompanying drawings. The relative terms are used for explanatory purposes only and does not imply that the device described is needed to be manufactured or operated in a specific orientation. It should be understood that if the device in the drawings is turned upside down, elements described as being at the “lower” side will become elements described as being at the “upper” side. The embodiments of the present disclosure may be understood in conjunction with the drawings. The drawings of the embodiments of the present disclosure may also be regarded as a part of the description of the embodiments of the present disclosure. It should be understood that the drawings of the embodiments of the present disclosure are not drawn to scale. In fact, the dimensions of the elements may be arbitrarily increased or reduced for clarity of the features of the present disclosure.

Unless otherwise defined, all terms (including technical and scientific terms) used herein have the same meaning as commonly understood by a person skilled in the art to which the disclosure pertains. It will be further understood that terms, such as those defined in commonly used dictionaries, should be interpreted as having a meaning consistent with the relevant technology and the context or background of this disclosure and will not be interpreted in an idealized or overly formal sense unless expressly so defined herein.

Some terms are used to refer to specific elements throughout the specification and the following claims of this disclosure. It should be understood by those of skill in the art that the same elements may be referred to by different names by electronic equipment manufacturers. It is not intended herein to distinguish between elements that are functionally identical but have different names. In the specification and claims below, the terms “comprise” and “include” are open-ended terms and should be interpreted to mean “contains but not limited to . . . ”.

The electronic device of the disclosure may include a display device, an antenna device, a sensing device, a touch display, a packaging device, a curved display, or a free shape display, but the disclosure is not limited thereto. The electronic device may be a bendable electronic device or a flexible electronic device. The antenna device may include a liquid-crystal type antenna, but the disclosure is not limited thereto. The packaging device may be suitable for Wafer-Level Package (WLP) technology or Panel-Level Package (PLP) technology, such as a chip first process or a RDL first process. It should be noted that electronic devices may include, but are not limited to, any combination thereof. In addition, the electronic device may have a rectangular shape, a round shape, a polygonal shape, a shape having curved edges, or other suitable shapes. The electronic device may include electronic components. The electronic components may include passive and active components, such as capacitors, resistors, inductors, diodes, transistors, and the like. The diodes may include a light emitting diode or a photovoltaic diode. The light emitting diode may, for example, include an organic light emitting diode (OLED), a sub-millimeter light emitting diode (mini LED), a micro light emitting diode (micro LED), or a quantum dot light emitting diode (quantum dot LED), but the disclosure is not limited thereto. The electronic devices may have a peripheral system such as a drive system, a control system, a light source system, a shelving system, and the like to support the display device, antenna device, or splicing device.

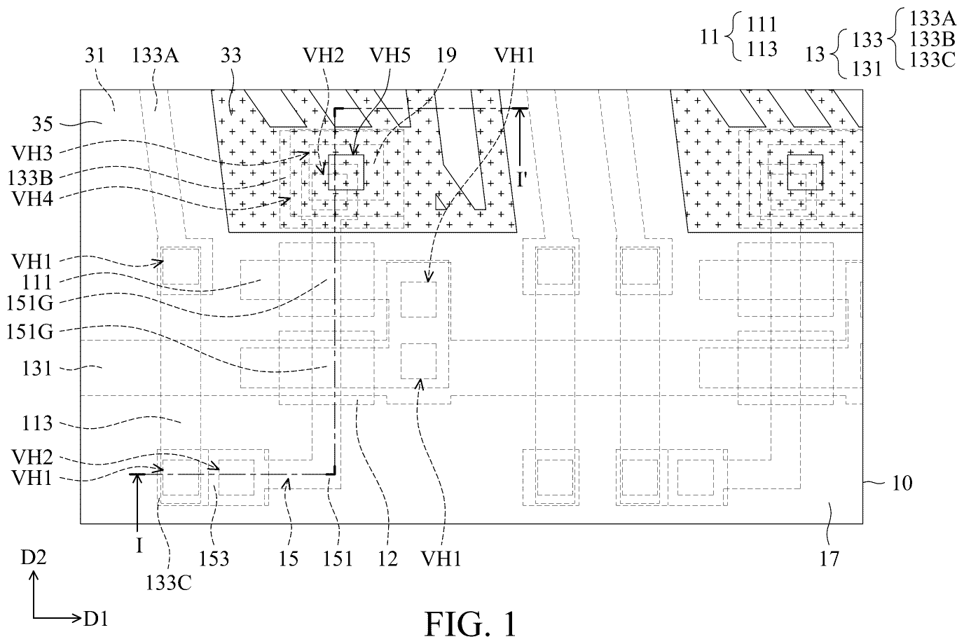

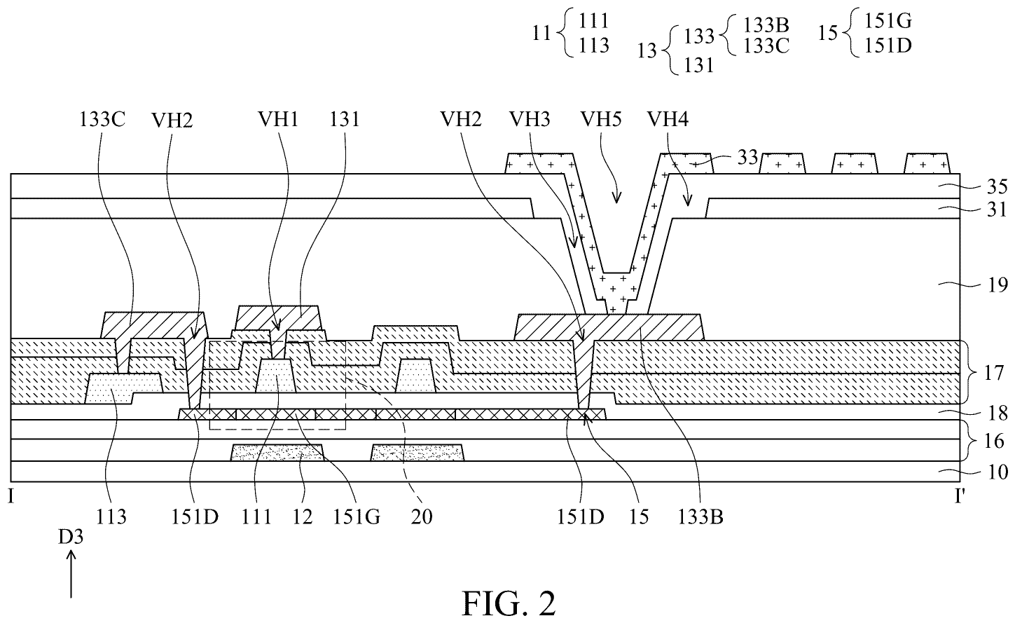

FIG. 1 is a partial top schematic view of a thin film transistor substrate according to an embodiment of the present disclosure. FIG. 2 is a partial cross-sectional schematic view of a thin film transistor substrate taken along a line I-I′ shown in FIG. 1. The thin film transistor substrate of the present disclosure includes a substrate 10, a first metal layer 11 disposed on the substrate 10, a second metal layer 13 disposed on the first metal layer 11, a semiconductor 15 disposed between the substrate 10 and the first metal layer 11, and a first insulating layer 17 disposed between the first metal layer 11 and the second metal layer 13. The first metal layer 11 includes a gate pattern 111, the second metal layer 13 includes a scan line pattern 131, the semiconductor 15 includes an active region 151G, and the first insulating layer 17 includes a first opening VH1. The gate pattern 111 overlaps the active region 151G. A thin film transistor 20 includes the semiconductor 15 and the gate pattern 111. The scan line pattern 131 of the second metal layer 13 is electrically connected to the gate pattern 111 of the first metal layer 11 through the first opening VH1 in the first insulating layer 17. In some embodiments, the thin film transistor substrate may further include a light shielding layer 12 disposed between the substrate 10 and the semiconductor 15. The light shielding layer 12 may overlap the active region 151G. In some embodiments, the thin film transistor substrate may further include a second insulating layer 19 disposed on the second metal layer 13, a first electrode layer 31 disposed on the second insulating layer 19, a second electrode layer 33 disposed on the first electrode layer 31, and a third insulating layer 35 disposed between the first electrode layer 31 and the second electrode layer 33, as shown in FIGS. 1 and 2. Here the term “overlap” means overlap in a normal direction of the substrate.

A material of the second insulating layer 19 may include a nitride, an oxide, a nitrogen oxide, a perfluoroalkoxyalkane (PFA), a resin, a photosensitive polyimide (PSPI), a polyimide (PI), an Ajinomoto build-up film (ABF), a polybenzoxazole (PBO), other suitable materials, or any combination thereof, but the disclosure is not limited thereto. The second insulating layer 19 may have a single layer structure or a multi-layer stacked structure. For example, the second insulating layer 19 may include a single layer of a silicon oxide, or the second insulating layer 19 may include a silicon nitride layer and a silicon oxide layer stacked along the normal direction of the substrate, but the disclosure is not limited thereto. In some embodiments, the second insulating layer 19 may include a third opening VH3. The third opening VH3 exposes a portion of the second metal layer 13.

The first electrode layer 31 is disposed on the second insulating layer 19 and may include a fourth opening VH4. In some embodiments, the fourth opening VH4 may be larger than the third opening VH3 and the third opening VH3 may be in the fourth opening VH4. In some embodiments, the fourth opening VH4 may expose a portion of the second metal layer 13. A material of the first electrode layer 31 may include a transparent conductive metal oxide. Examples of the transparent conductive metal oxides may include an indium oxide (In₂O₃), a tin oxide (SnO₂), a zinc oxide (ZnO), an indium tin oxide (ITO), an indium zinc oxide (IZO), a fluorine doped tin oxide, a graphene nanoribbon, or a metal nanowire, but the disclosure is not limited thereto.

A material of the third insulating layer 35 may include a nitride, an oxide, a nitrogen oxide, a perfluoroalkoxyalkane (PFA), a resin, a photosensitive polyimide (PSPI), a polyimide (PI), an Ajinomoto build-up film (ABF), a polybenzoxazole (PBO), other suitable materials, or any combination thereof, but the disclosure is not limited thereto. The third insulating layer 35 may have a single layer structure or a multi-layer stacked structure. For example, the third insulating layer 35 may include a single layer of a silicon nitride, or the third insulating layer 35 may include a silicon nitride layer and a silicon oxide layer stacked along the normal direction of the substrate, but the disclosure is not limited thereto. The third insulating layer 35 may include a fifth opening VH5. In some embodiments, the fifth opening VH5 may be smaller than the fourth opening VH4 and the third opening VH3 and in the third opening VH3 and the fourth opening VH4, as shown in FIG. 2. The fifth opening VH5 may expose a portion of the second metal layer 13.

A material of the second electrode layer 33 may include a transparent conductive metal oxide. Examples of the transparent conductive metal oxides may include an indium oxide (In₂O₃), a tin oxide (SnO₂), a zinc oxide (ZnO), an indium tin oxide (ITO), an indium zinc oxide (IZO), a fluorine doped tin oxide, a graphene nanoribbon, or a metal nanowire, but the disclosure is not limited thereto. The materials of the first electrode layer 31 and the second electrode layer 33 may be the same or different. In some embodiments, the second electrode layer 33 has a grid structure, i.e., the second electrode layer 33 has a grid shape in a top view of the thin film transistor substrate, as shown in FIG. 1. In some embodiments, the second electrode layer 33 is electrically connected to the semiconductor 15 through the fifth opening VH5 and the second metal layer 13.

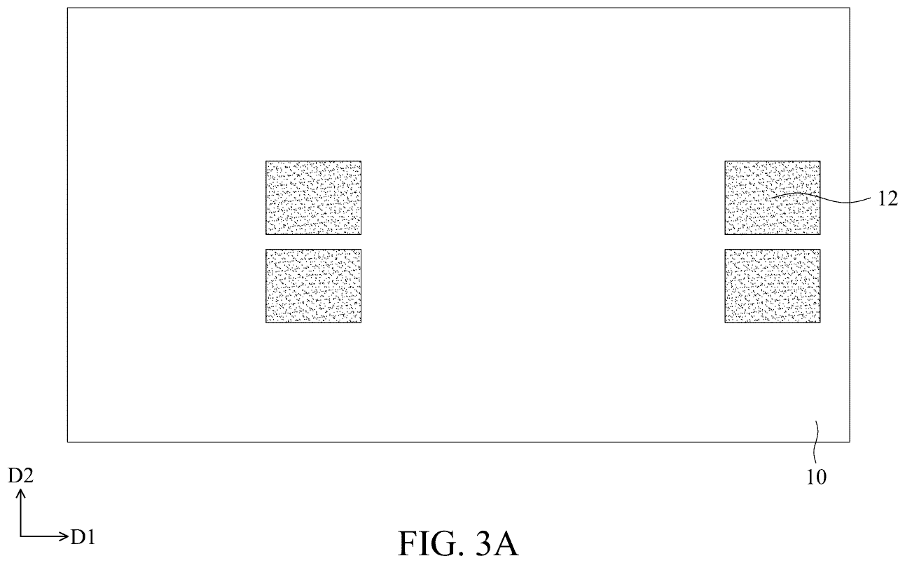

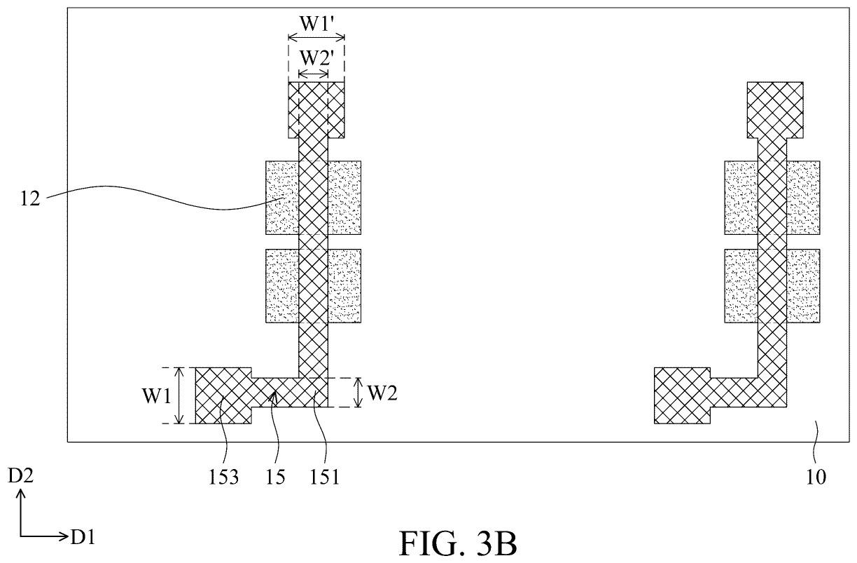

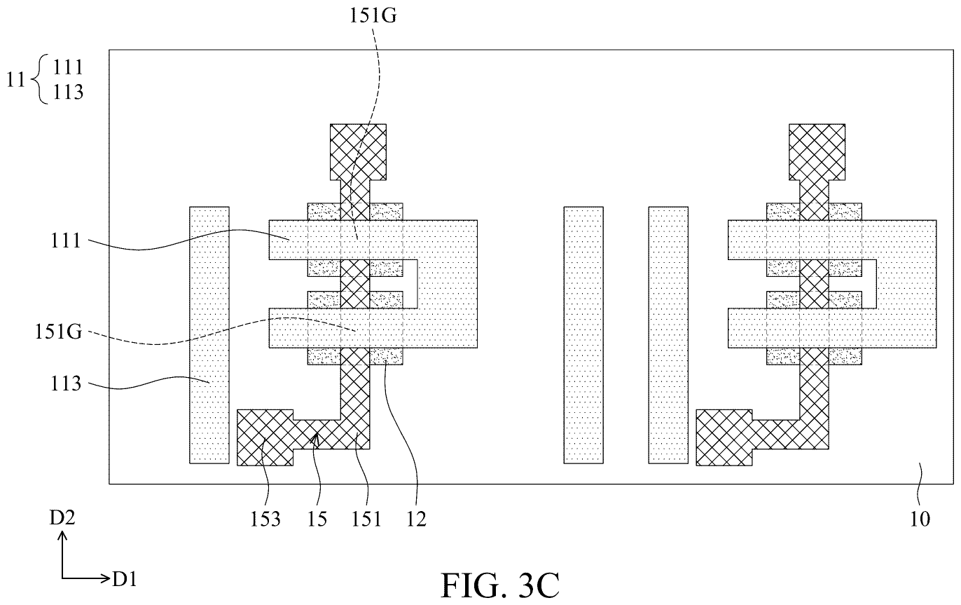

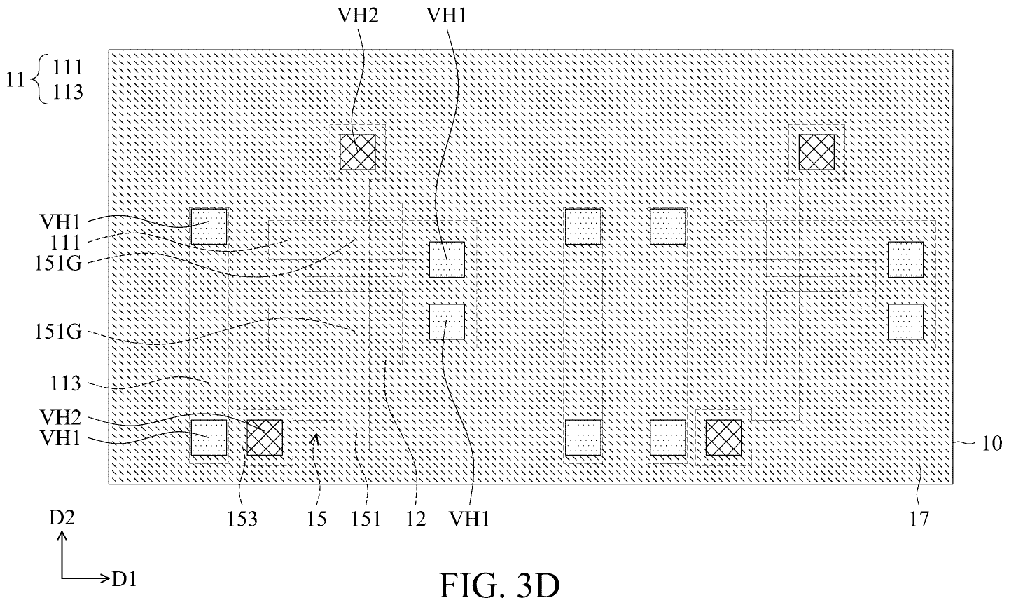

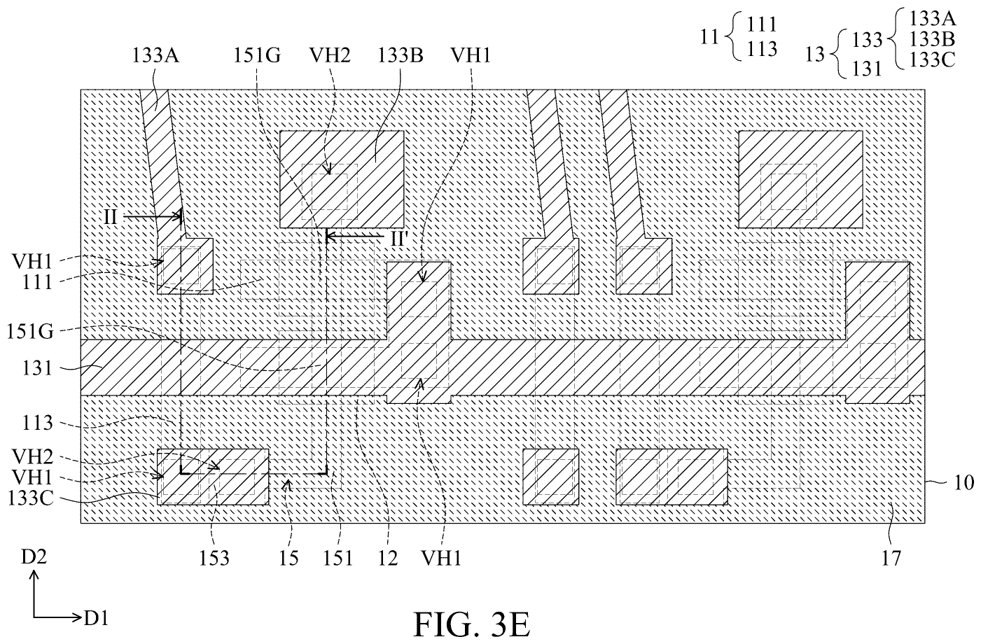

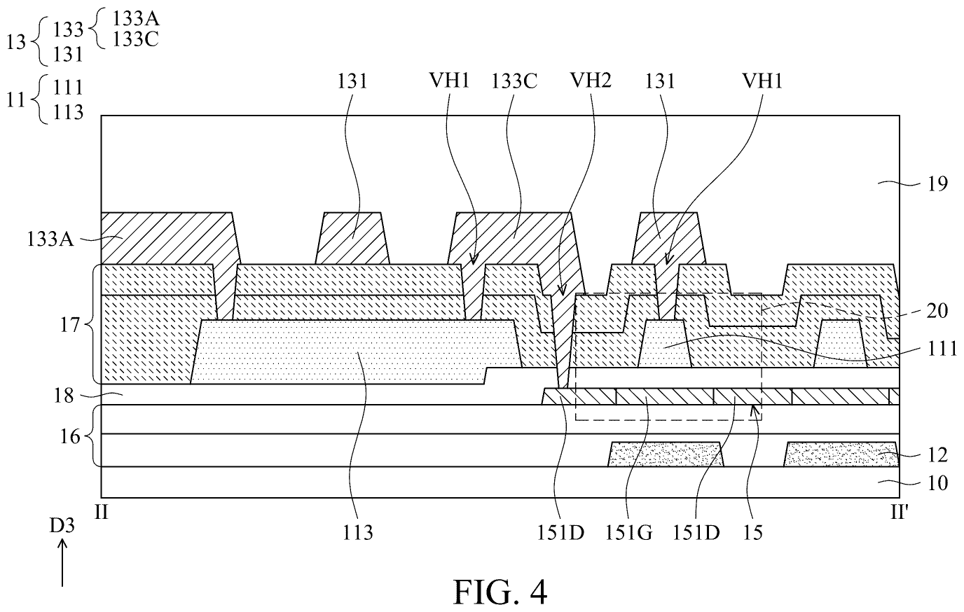

FIGS. 3A to 3E are partial top schematic views of structures in which a light shielding layer 12, a semiconductor 15, a first metal layer 11, a first insulating layer 17, and a second metal layer 13 are sequentially formed on a substrate 10 according to an embodiment of the present disclosure respectively. FIG. 4 is a partial cross-sectional schematic view of the structure shown in FIG. 3E taken along a line II-II′. The structure of a thin film transistor substrate of an embodiment of the present disclosure is further described with reference to FIGS. 3A to 3E and FIG. 4.

FIG. 3A is a partial top schematic view of a structure in which the light shielding layer 12 is formed on the substrate 10 according to an embodiment of the present disclosure. The light shielding layer 12 may include a plurality of island patterns, as shown in FIG. 3A, but the disclosure is not limited thereto. In some embodiments, the substrate 10 may include a transparent or opaque organic or inorganic material, as well as a rigid or flexible material. Examples of the organic material may include a polyimide (PI), a polycarbonate (PC), a polyethylene terephthalate (PET), a liquid-crystal polymer (LCP), other known suitable materials, or combinations of the foregoing, but the disclosure is not limited thereto. Examples of the inorganic material may include a dielectric material or a metallic material, but the disclosure is not limited thereto. Examples of the rigid material may include a glass, a quartz, a sapphire, a ceramic or a plastic, or any suitable materials. The term “flexible material” herein refers to a material that can be curved, bent, folded, rolled, flexible, stretched, and/or other similar deformations. Examples of the flexible materials may include one of the organic material described above, but the flexible material in the disclosure is not limited to the foregoing. The substrate may further include through-holes passing through the substrate in the normal direction of the substrate, drive circuits, compensation circuits, and optical fibers or conductive materials disposed in the through-holes, but the disclosure is not limited thereto. The light shielding layer 12 may include a black matrix or a metal, wherein a material of the black matrix may include an organic insulating material (e.g., photosensitive resin) or a metallic material, but the disclosure is not limited thereto.

The semiconductor 15 is formed on the structure of FIG. 3A and at least partially overlaps the light shielding layer 12, as shown in FIG. 3B. The semiconductor 15 may include a body 151 and an end portion 153. The body 151 may have various shapes. In some embodiments, the body 151 may have an L-shaped structure, as shown in FIG. 3B, but the disclosure is not limited thereto. In some embodiments, the body 151 may have an I-shaped structure, a U-shaped structure, a Y-shaped structure, or a T-shaped structure, but the disclosure is not limited thereto. The term “L-shaped structure”, “I-shaped structure”, “U-shaped structure”, “Y-shaped structure”, or “T-shaped structure” herein refers to a structure having an L-shape, an I-shape, a U-shape, a Y-shape, or a T-shape in a top view perpendicular to the thin film transistor substrate. The body 151 is connected to the end portion 153 in an extension direction. In an embodiment, the width of the end portion 153 of the semiconductor 15 is greater than the width of the body 151 of the semiconductor 15 in a direction that is perpendicular to the extension direction, but the disclosure is not limited thereto. Specifically, in some embodiments, in an embodiment in which the body 151 has an L-shaped structure, the semiconductor 15 may include the body 151 having a horizontal portion extending along a first direction D1 and an end portion 153 connected to the horizontal portion of the body 151 and a vertical portion extending along a second direction D2 and an end portion 153 connected to the vertical portion of the body 151, as shown in FIG. 3B. In the second direction D2 perpendicular to the first direction D1, the width W1 of the end portion 153 connected to the horizontal portion of the body 151 is greater than the width W2 of the horizontal portion of the body 151. In the first direction D1, which is perpendicular to the second direction D2, the width W1′ of the end portion 153 connected to the vertical portion of the body 151 is greater than the width W2′ of the vertical portion of the body 151. The width W1 of the end portion 153 connected to the horizontal portion of the body 151 may be the same as or different from the width W1′ of the end portion 153 connected to the vertical portion of the body 151. The width W2 of the horizontal portion of the body 151 may be the same as or different from the width W2′ of the vertical portion of the body 151.

The body 151 of the semiconductor 15 may include source/drain regions 151D and an active region 151G disposed between the source/drain regions 151D. Depending on portions of the body 151 of the semiconductor 15 that overlap the first metal layer 11 and the second metal layer 13, the body 151 of the semiconductor 15 may include more than one active region 151G. For example, one of the semiconductors 15 of the thin film transistor substrate illustrated in FIG. 1 includes two active regions 151G, but the present disclosure is not limited thereto. The semiconductor 15 may include an amorphous silicon (A-Si), a low temperature polysilicon (LTPS), an indium gallium zinc oxide (IGZO), an indium gallium oxide (IGO), or other metal oxide semiconductor materials commonly used in the art, or any combination thereof, but the disclosure is not limited thereto. The source/drain regions 151D may be doped with an n-type dopant (e.g., phosphorus or arsenic) and/or a p-type dopant (e.g., boron or BF₂). The source/drain regions 151D may be formed by implantation of dopant atoms, in situ doped epitaxial growth, other suitable techniques, or a combination thereof.

In some embodiments, a first interlayer insulating layer 16 is further formed between the semiconductor 15 and the light shielding layer 12, as shown in FIG. 1 and FIG. 4. In some embodiments, a material of the first interlayer insulating layer 16 may include a nitride, an oxide, a nitrogen oxide, a perfluoroalkoxyalkane (PFA), a resin, a photosensitive polyimide (PSPI), a polyimide (PI), an Ajinomoto build-up film (ABF), a polybenzoxazole (PBO), other suitable materials, or any combination thereof, but the disclosure is not limited thereto. The first interlayer insulating layer 16 may have a single layer structure or a multi-layer stacked structure. For example, the first interlayer insulating layer 16 may include a single layer of a silicon oxide, or the first interlayer insulating layer 16 may include a silicon nitride layer and a silicon oxide layer stacked along the normal direction of the substrate, but the disclosure is not limited thereto.

The first metal layer 11 is formed on the structure of FIG. 3B, as shown in FIG. 3C. The first metal layer 11 includes a gate pattern 111 that at least partially overlaps the active region 151G of the semiconductor 15, and a first conductive pattern 113. The gate pattern 111 may have various shapes. In some embodiments, the gate pattern 111 may have a U-shaped structure, as shown in FIG. 3C, but the disclosure is not limited thereto. The gate pattern 111 may have an I-shaped structure, an L-shaped structure, a Y-shaped structure, or a T-shaped structure. The first conductive pattern 113 and the gate pattern 111 are electrically insulated from each other and spatially separated by a distance. In some embodiments, the first conductive pattern 113 does not overlap the semiconductor 15. The first conductive pattern 113 may have various shapes. In some embodiments, the first conductive pattern 113 may have an I-shaped structure, as shown in FIG. 3C, but the disclosure is not limited thereto. The first conductive pattern 113 may have a U-shaped structure, an L-shaped structure, a Y-shaped structure, or a T-shaped structure. The definitions of the “L-shaped structure”, “I-shaped structure”, “U-shaped structure”, “Y-shaped structure”, or “T-shaped structure” herein are the same as the above.

The gate pattern 111 is used as a gate electrode of the thin film transistor 20. The semiconductor 15 is used as an active layer of the thin film transistor 20. That is, the thin film transistor 20 includes at least a portion of the semiconductor 15 and the gate pattern 111 of the first metal layer 11.

In some embodiments, a material of the first metal layer 11 may include copper (Cu), aluminum (Al), molybdenum (Mo), tungsten (W), gold (Au), chromium (Cr), nickel (Ni), platinum (Pt), titanium (Ti), another suitable metallic material, or a combination thereof. In some embodiments, the first metal layer 11 may have a single layer structure or a multi-layer stacked structure. For example, the first metal layer 11 may include a single layer of metallic copper, or the first metal layer 11 may include a metallic titanium layer and a metallic copper layer stacked along the normal direction of the substrate, but the disclosure is not limited thereto.

In some embodiments, a second interlayer insulating layer 18 is further formed between the semiconductor 15 and the first metal layer 11 to electrically insulate the first metal layer 11 from the semiconductor 15, as shown in FIG. 1 and FIG. 4. In some embodiments, a material of the second interlayer insulating layer 18 may include a nitride, an oxide, a nitrogen oxide, a perfluoroalkoxyalkane (PFA), a resin, a photosensitive polyimide (PSPI), a polyimide (PI), an Ajinomoto build-up film (ABF), a polybenzoxazole (PBO), other suitable materials, or any combination thereof, but the disclosure is not limited thereto. The second interlayer insulating layer 18 may have a single layer structure or a multi-layer stacked structure. For example, the second interlayer insulating layer 18 may include a single layer of a silicon oxide, or the second interlayer insulating layer 18 may include a silicon nitride layer and a silicon oxide layer stacked along the normal direction of the substrate, but the disclosure is not limited thereto.

The first insulating layer 17 is formed on the structure of FIG. 3C to cover the first metal layer 11, as shown in FIG. 3D and FIG. 4. The first insulating layer 17 includes a first opening VH1. The first opening VH1 penetrates through the first insulating layer 17. In some embodiments, the first opening VH1 may overlap a portion of the first metal layer 11. The portion of the first metal layer 11 is exposed by the first opening VH1. In some embodiments, the thin film transistor substrate includes a second opening VH2. The second opening VH2 penetrates through the first insulating layer 17 and the second interlayer insulating layer 18. In some embodiments, the second opening VH2 may overlap an end portion 153 of the semiconductor 15. The end portion 153 of the semiconductor 15 is exposed by the second opening VH2.

In some embodiments, a material of the first insulating layer 17 may include a nitride, an oxide, a nitrogen oxide, a perfluoroalkoxyalkane (PFA), a resin, a photosensitive polyimide (PSPI), a polyimide (PI), an Ajinomoto build-up film (ABF), a polybenzoxazole (PBO), other suitable materials, or any combination thereof, but the disclosure is not limited thereto. The first insulating layer 17 may have a single layer structure or a multi-layer stacked structure. For example, the first insulating layer 17 may include a single layer of a silicon oxide, or the first insulating layer 17 may include a silicon nitride layer and a silicon oxide layer stacked along the normal direction of the substrate, but the disclosure is not limited thereto.

The second metal layer 13 is formed on the structure of FIG. 3D, as shown in FIG. 3E. The second metal layer 13 includes a scan line pattern 131 and a second conductive pattern 133. The scan line pattern 131 and the second conductive pattern 133 are electrically insulated from each other and spatially separated by a distance. The scan line pattern 131 at least partially overlaps the active region 151G of the semiconductor 15 and the gate pattern 111 of the first metal layer 11. In some embodiments, the scan line pattern 131 at least partially overlaps the first conductive pattern 113 of the first metal layer 11 (see FIG. 1). In some embodiments, the scan line pattern 131 extends in an extension direction. In a direction perpendicular to the extension direction, the width of the at least portion of the scan line pattern 131 that overlaps the gate pattern 111 is greater than the width of the remaining portion of the scan line pattern 131. In some embodiments, as shown in FIG. 4, the scan line pattern 131 is electrically connected to the gate pattern 111 of the first metal layer 11 through the first opening VH1 of the first insulating layer 17.

In some embodiments, the second conductive pattern 133 includes a first portion 133A, a second portion 133B, and a third portion 133C. The first portion 133A overlaps the first metal layer 11 but not overlaps the semiconductor 15. The second portion 133B overlaps the semiconductor 15 but not overlaps the first metal layer 11. The third portion 133C overlaps the first metal layer 11 and the semiconductor 15. In some embodiments, the first portion 133A is electrically connected to the first conductive pattern 113 of the first metal layer 11 through a first opening VH1 of the first insulating layer 17. The second portion 133B is electrically connected to the semiconductor 15 through a second opening VH2. More specifically, the second portion 133B of the second conductive pattern 133 is electrically connected to the source/drain regions 151D of the semiconductor 15 through the second opening VH2, as shown in FIG. 4. The third portion 133C is electrically connected to the first conductive pattern 113 and the semiconductor 15 through the first opening VH1 and the second opening VH2, respectively. In some embodiments, the first portion 133A and the third portion 133C of the second conductive pattern 133 are electrically connected to each other through the first conductive pattern 113 of the first metal layer 11, as shown in FIG. 4. In some embodiments, the second conductive pattern 133 may include a portion of a data line providing data signals to the semiconductor 15. In some embodiments, the portion of the first portion 133A and the third portion 133C of the second conductive pattern 133 may be used as a data line providing data signals to the semiconductor 15.

In some embodiments, a material of the second metal layer 13 may include a metallic material having a resistance value greater than 0 and less than 7 μΩ·m. The material of the second metal layer 13 may include aluminum (Al). The material of the second metal layer 13 may be the same as or different from the material of the first metal layer 11. In some embodiments, the second metal layer 13 may have a single layer structure or a multi-layer stacked structure. For example, the second metal layer 13 may include a single layer of metallic aluminum, but the disclosure is not limited thereto.

The second insulating layer 19, the first electrode layer 31 disposed on the second insulating layer 19, the second electrode layer 33 disposed on the first electrode layer 31, and the third insulating layer 35 disposed between the first electrode layer 31 and the second electrode layer 33 may be further formed on a structure of FIG. 3E to complete the preparation of the thin film transistor substrate, but the present disclosure is not limited thereto. In some embodiments, the second insulating layer 19, the first electrode layer 31, the second electrode layer 33, the third insulating layer 35, or any combination thereof may be omitted.

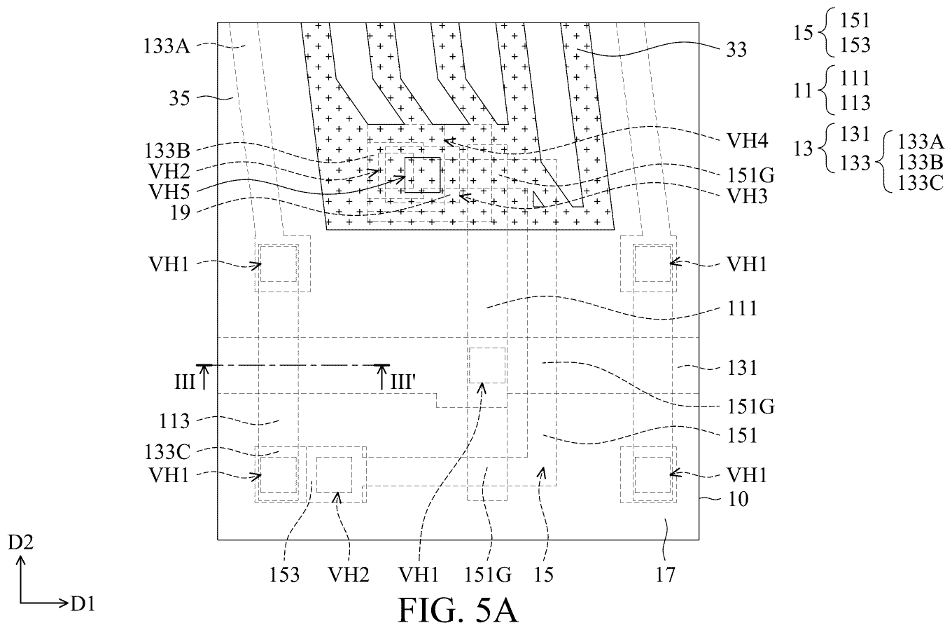

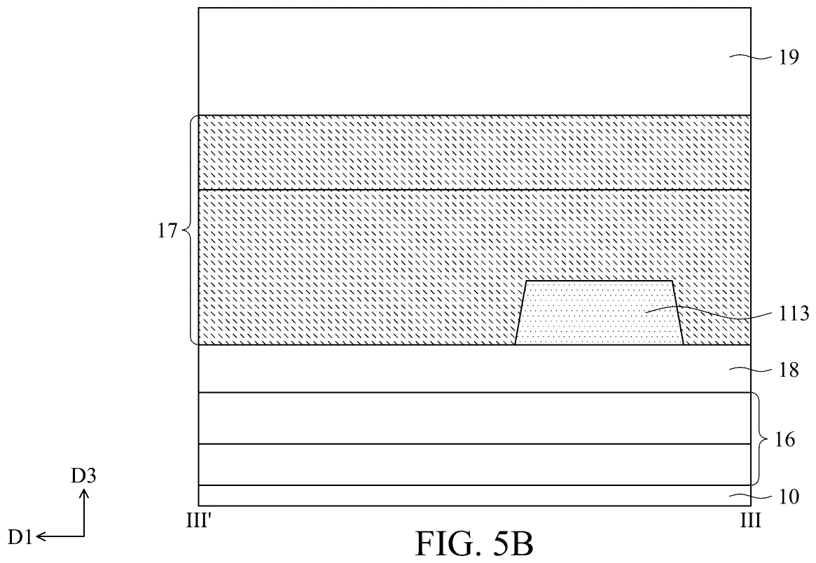

FIGS. 1 to 4 illustrate a semiconductor having an L-shaped structure and two active regions in the thin film transistor substrate as an example, but the present disclosure is not limited thereto. In some embodiments, the body of the semiconductor may have a U-shaped structure. In some embodiments, the semiconductor may have three active regions. Other aspects of the thin film transistor substrates of the present disclosure are described below with reference to FIGS. 5A to 8.

FIG. 5A is a partial top schematic view of a thin film transistor substrate according to an embodiment of the present disclosure. FIG. 5B is a partial cross-sectional schematic view of the structure shown in FIG. 5A taken along a line III-III′. Except for the first metal layer 11, the second metal layer 13, the semiconductor 15, and the first insulating layer 17 having a single-layer structure, the other elements of the thin film transistor substrate are substantially the same as those described in the thin film transistor substrate described with reference to FIGS. 1 to 4. Therefore, the following describes only the structure of the first metal layer 11, the second metal layer 13, and the semiconductor 15.

The semiconductor 15 is formed on the substrate 10, the first metal layer 11 is formed on the semiconductor 15, and the second metal layer 13 is formed on the first metal layer 11, as shown in FIG. 5B.

As shown in FIG. 5A, the body 151 of the semiconductor 15 has a U-shaped structure. The first metal layer 11 includes a gate pattern 111 that at least partially overlaps the active region 151G of the semiconductor 15 and a first conductive pattern 113. The gate pattern 111 has an I-shaped structure. The second metal layer 13 includes a scan line pattern 131 and a second conductive pattern 133, wherein a portion of the scan line pattern 131 overlaps the active region 151G of the semiconductor 15. Depending on portions of the body 151 of the semiconductor 15 that overlap the first metal layer 11 and the second metal layer 13, the body 151 of the semiconductor 15 may include three active regions 151G as shown in FIG. 5A. The gate pattern 111 and the portions of the scan line pattern 131 are used as gate electrodes of the thin film transistor 20. The semiconductor 15 is used as an active layer of the thin film transistor 20. In the embodiment shown in FIG. 5A, the scan line pattern 131 of the second metal layer 13 is electrically connected to the gate pattern 111 of the first metal layer 11 through a first opening VH1 of the first insulating layer 17.

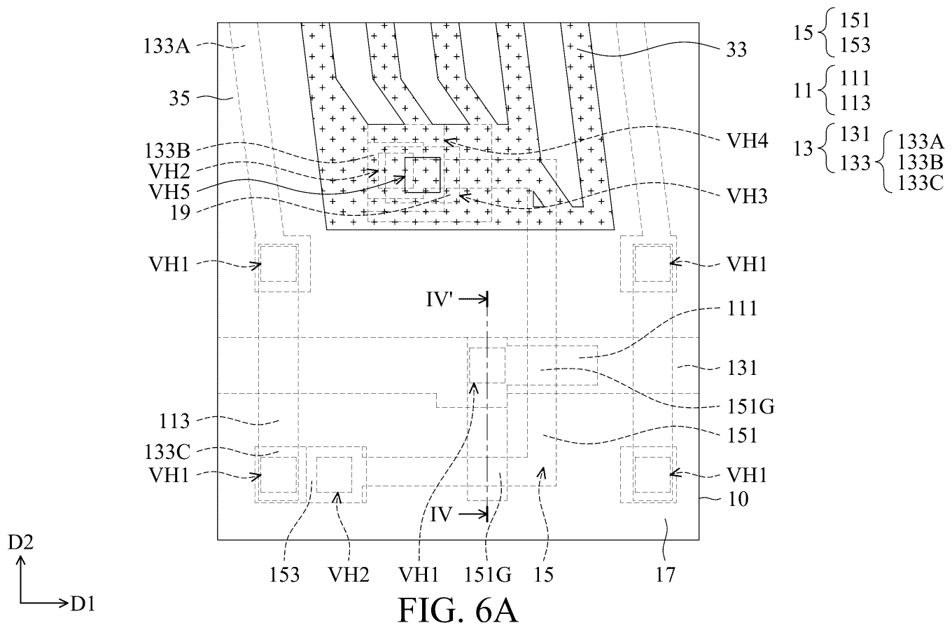

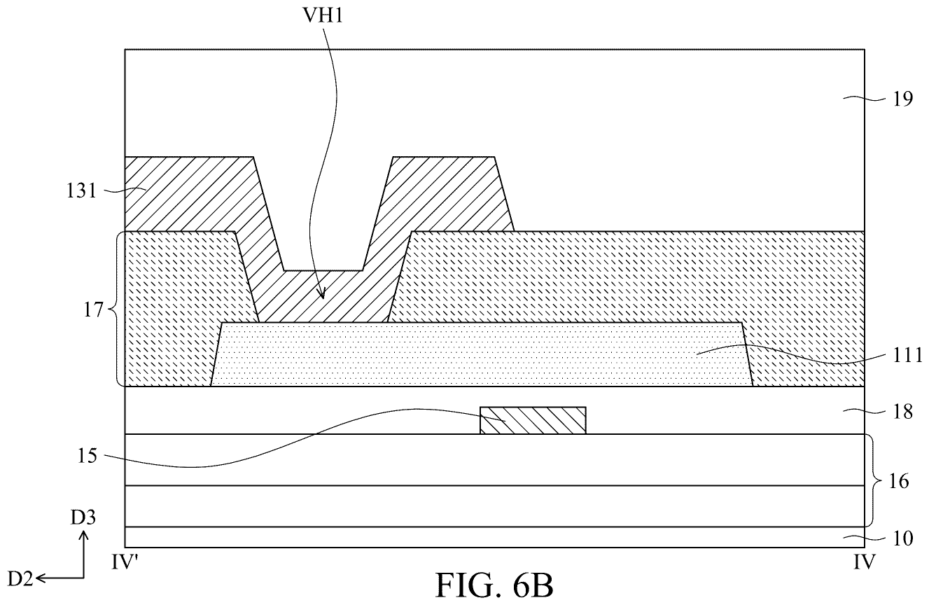

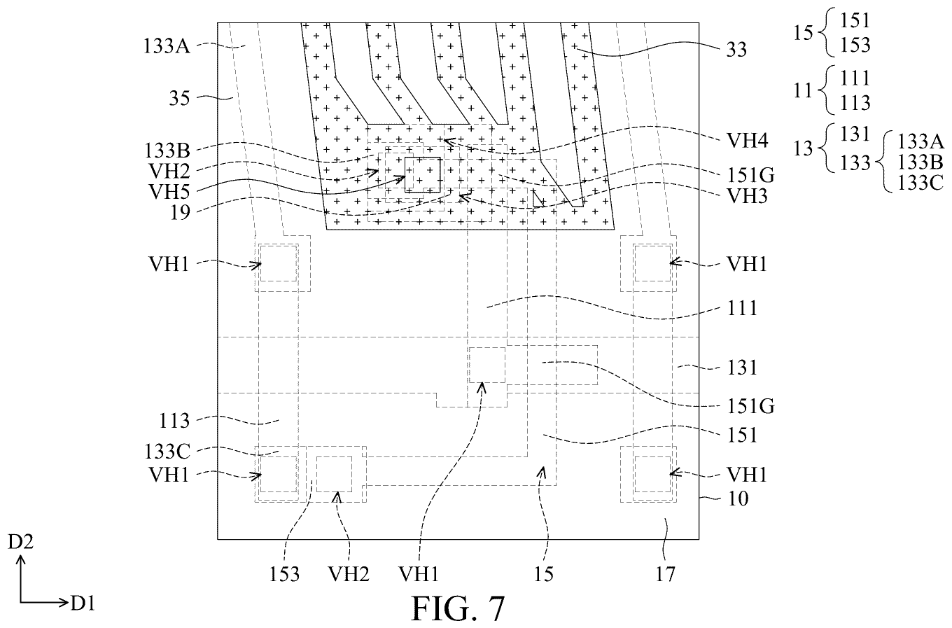

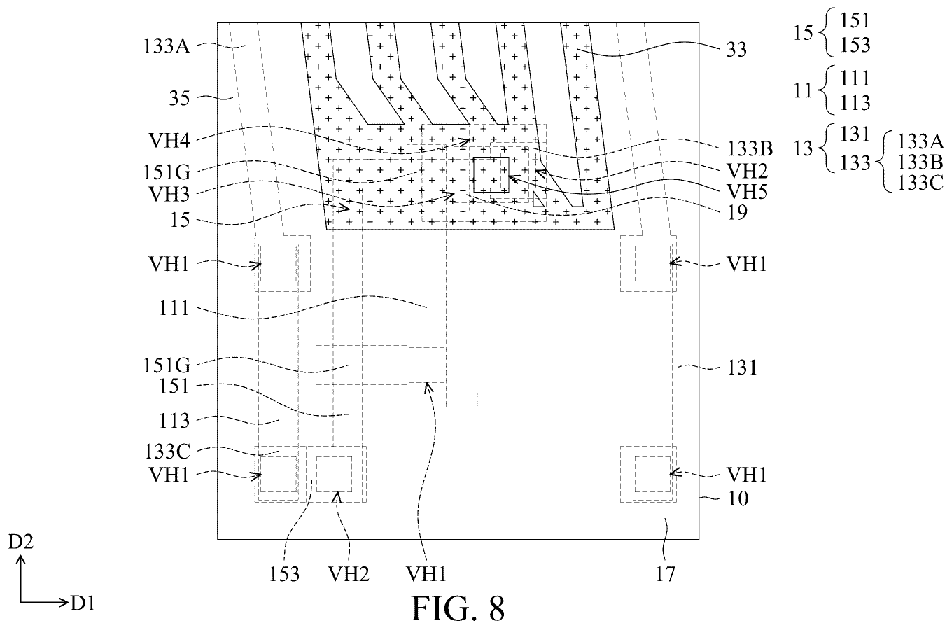

FIG. 6A is a partial top schematic view of a thin film transistor substrate according to an embodiment of the present disclosure. FIG. 6B is a partial cross-sectional schematic view of the structure shown in FIG. 6A taken along a line IV-IV′. Except that the body 151 of the semiconductor 15 has a U-shaped structure, the gate pattern 111 of the first metal layer 11 has an L-shaped structure, and the first insulating layer 17 has a single-layer structure, the other elements of the thin film transistor substrate are substantially the same as those of the thin film transistor substrate described with reference to FIGS. 1 to 4. Therefore, the thin film transistor substrate described with reference to FIGS. 6A and 6B will not be repeated herein. FIG. 7 is a partial top schematic view of a thin film transistor substrate according to an embodiment of the present disclosure. Except that the body 151 of the semiconductor 15 has a U-shaped structure and the gate pattern 111 of the first metal layer 11 has an L-shaped structure, the other elements of the thin film transistor substrate are substantially the same as those of the thin film transistor substrate described with reference to FIGS. 1 to 4. Therefore, the thin film transistor substrate described with reference to FIG. 7 will not be repeated herein. FIG. 8 is a partial top schematic view of a thin film transistor substrate according to an embodiment of the present disclosure. Except that the body 151 of the semiconductor 15 has an L-shaped structure and the gate pattern 111 of the first metal layer 11 has an L-shaped structure, the other elements of the thin-film transistor substrate are substantially the same as those of the thin-film transistor substrate described with reference to FIGS. 1 to 4. Therefore, the thin film transistor substrate described with reference to FIG. 8 will not be repeated herein.

Another aspect of the present disclosure provides an electronic device including a thin film transistor substrate comprising a thin film transistor.

The structure of the thin film transistor substrate comprising a thin film transistor is similar to the structure of any of the thin film transistor substrates described above, and will not be repeated herein.

With the above structure, the thin film transistor substrate disclosed herein can significantly reduce the scanning line load and is suitable for large size panels. In addition, the thin-film transistor substrate disclosed herein can be prepared with a smaller number of photomasks, and thus the process can be simplified or the manufacturing cost can be reduced. The electronic devices including the thin film transistor substrate disclosed herein may also have advantages such as low scan line load, low manufacturing cost, or simplified manufacturing process.

Although embodiments of the present disclosure and the advantages thereof have been disclosed as above, it should be understood that changes, substitutions and modifications may be made without departing from the spirit and scope of the disclosure. In addition, the protection scope of the present disclosure is not limited to the processes, machines, fabrications, compositions, devices, methods and steps in the specific embodiments described in the specification. According to the embodiments of the present disclosure, a person of ordinary skill in the art may understand that current or future processes, machines, fabrications, compositions, devices, methods and steps capable of performing substantially the same functions or achieving substantially the same results may be used in the embodiments of the present disclosure. Therefore, the protection scope of the present disclosure includes the above-mentioned processes, machines, fabrications, compositions, devices, methods and steps. In addition, each claims constitutes an individual embodiment, and a protection scope of the present disclosure also includes a combination of each claims and embodiment. As long as the features of each embodiments do not violate the spirit of the invention or conflict with each other, they can be mixed and matched arbitrarily.

What is claimed is:

1. A thin film transistor substrate, comprising:
a substrate;
a first metal layer disposed on the substrate and comprising a gate pattern;
a second metal layer disposed on the first metal layer and comprising a scan line pattern;
a semiconductor disposed between the substrate and the first metal layer and comprising an active region; and
a first insulating layer disposed between the first metal layer and the second metal layer and comprising a first opening,
wherein the gate pattern overlaps the active region, and
the scan line pattern of the second metal layer is electrically connected to the gate pattern of the first metal layer through the first opening in the first insulating layer.

2. The thin film transistor substrate as claimed in claim 1, wherein the semiconductor comprises a body and an end portion, wherein the body has an L-shaped structure, an I-shaped structure, a U-shaped structure, a Y-shaped structure, or a T-shaped structure.

3. The thin film transistor substrate as claimed in claim 2, wherein the body is connected to the end portion in an extension direction, and in a second direction perpendicular to the extension direction, a width of the end portion of the semiconductor is greater than a width the body of the semiconductor.

4. The thin film transistor substrate as claimed in claim 1, wherein the gate pattern has an L-shaped structure, an I-shaped structure, a U-shaped structure, a Y-shaped structure, or a T-shaped structure.

5. The thin film transistor substrate as claimed in claim 1, wherein the first metal layer further comprises a first conductive pattern, the first conductive pattern and the gate pattern are electrically insulated from each other and spatially separated by a distance, and the first conductive pattern does not overlap the semiconductor.

6. The thin film transistor substrate as claimed in claim 5, wherein the second metal layer further comprises a second conductive pattern, and the second conductive pattern comprises:
a first portion overlapping the first metal layer but not overlapping the semiconductor;
a second portion overlapping the semiconductor but not overlapping the first metal layer; and
a third portion overlapping the first metal layer and the semiconductor.

7. The thin film transistor substrate as claimed in claim 6, wherein the first portion is electrically connected to the first conductive pattern of the first metal layer through the first opening of the first insulating layer.

8. The thin film transistor substrate as claimed in claim 6, wherein the first portion and the third portion are electrically connected to each other through the first conductive pattern of the first metal layer.

9. The thin film transistor substrate as claimed in claim 1, further comprising a first electrode layer disposed on the second metal layer and a second electrode layer disposed on the first electrode layer, wherein the second electrode layer is electrically connected to the semiconductor.

10. The thin film transistor substrate as claimed in claim 9, wherein the first electrode layer and the second electrode layer comprise a transparent conductive metal oxide.

11. The thin film transistor substrate as claimed in claim 1, wherein the second metal layer comprises a metallic material having a resistance value greater than 0 and less than 7 μΩ·m.

12. The thin film transistor substrate as claimed in claim 11, wherein the second metal layer comprises aluminum (Al).

13. The thin film transistor substrate as claimed in claim 1, wherein at least a portion of the scan line pattern overlaps another active region of the semiconductor.

14. An electronic device comprising a thin film transistor substrate, wherein the thin film transistor substrate comprises:
a substrate;
a first metal layer disposed on the substrate and comprising a gate pattern;
a second metal layer disposed on the first metal layer and comprising a scan line pattern;
a semiconductor disposed between the substrate and the first metal layer and comprising an active region; and
a first insulating layer disposed between the first metal layer and the second metal layer and comprising a first opening,
wherein the gate pattern overlaps the active region, and
the scan line pattern of the second metal layer is electrically connected to the gate pattern of the first metal layer through the first opening in the first insulating layer.

15. The electronic device as claimed in claim 14, wherein the second metal layer comprises a metallic material having a resistance value greater than 0 and less than 7 μΩ·m.

16. The electronic device as claimed in claim 14, wherein the thin film transistor substrate further comprises a first electrode layer disposed on the second metal layer and a second electrode layer disposed on the first electrode layer, wherein the second electrode layer is electrically connected to the semiconductor.

17. The electronic device as claimed in claim 14, wherein the first metal layer further comprises a first conductive pattern, the first conductive pattern and the gate pattern are electrically insulated from each other and spatially separated by a distance, and the first conductive pattern does not overlap the semiconductor.

18. The electronic device as claimed in claim 14, wherein the second metal layer further comprises a second conductive pattern, and the second conductive pattern comprises:
a first portion overlapping the first metal layer but not overlapping the semiconductor;
a second portion overlapping the semiconductor but not overlapping the first metal layer; and
a third portion overlapping the first metal layer and the semiconductor.

19. The electronic device as claimed in claim 18, wherein the first portion and the third portion are electrically connected to each other through the first conductive pattern of the first metal layer.

20. The electronic device as claimed in claim 18, wherein the first portion is electrically connected to the first conductive pattern of the first metal layer through a first opening of the first insulating layer.
